(19) United States
(12) Patent Application Publication
(10) Pub. No.: US 2009/0184405 A1
(43) Pub. Date: Jul. 23, 2009

(54) Package structure

(75) Inventor: Hsin-Chieh Lu, Kaohsiung (TW)

Correspondence Address: BACON & THOMAS, PLLC, 625 SLATERS LANE, FOURTH FLOOR, ALEXANDRIA, VA, 22314-1176, US

(73) Assignee: Advanced Semiconductor Engineering, Inc., Kaohsiung (TW)

(21) Appl. No.: 12/213,719

(22) Filed: Jun. 24, 2008

(30) Foreign Application Priority Data
Jan. 23, 2008 (TW) 97102568

(51) Int. Cl. H01L 23/552

(52) U.S. Cl. 257/660; 257/E23.114

(57) ABSTRACT

A package structure is provided. The package structure includes a substrate, a semiconductor device, and a shielding cap. The substrate has at least an alignment recess located at a corner of the substrate. The semiconductor device is disposed on an upper surface of the substrate. The shielding cap having an alignment pin covers the semiconductor device. The alignment pin is inserted into the alignment recess.

This application claims the benefit of Taiwan application Serial No. 097102568, filed Jan. 23, 2008, the subject matter of which is incorporated herein by reference.

### BACKGROUND OF THE INVENTION

1. Field of the Invention

The invention relates in general to a package structure, and more particularly to a package structure having a shielding cap.

2. Description of the Related Art

As semiconductor packaging technology develops, the package structure becomes more and more complicated. For example, some processing chips and communication chips need shielding caps to protect the chips from being interfered with outer radiation, or to prevent the radiation generated by the chips from affecting other electronic units.

However, during the reflow process, the shielding cap moves easily due to convection of hot air, which may cause instability of the shielding cap, poor shielding capacity or short circuit.

### SUMMARY OF THE INVENTION

The invention is directed to a package structure using the design of a substrate and a shielding cap for stably alignment the shielding cap on the substrate and providing good shielding.

According to the present invention, a package structure is provided. The package structure includes a substrate, a semiconductor device and a shielding cap. The substrate has at least an alignment recess at a corner of the substrate. The semiconductor device is disposed on an upper surface of the substrate. The shielding cap including an alignment pin covers the semiconductor device. The alignment pin is inserted into the alignment recess.

The invention will become apparent from the following detailed description of the preferred but non-limiting embodiments. The following description is made with reference to the accompanying drawings.

### BRIEF DESCRIPTION OF THE DRAWINGS

FIG. 1 is an exploded view of a package structure according to a first embodiment of the present invention;

FIG. 2 is an assembled view of the package structure in FIG. 1;

FIG. 3 illustrates an alignment pin and an alignment recess;

FIG. 4 is a lateral view of the package structure in FIG. 2;

FIG. 5 illustrates a mother substrate;

FIG. 6 illustrates a projection of a shielding cap and a substrate; and

FIG. 7 illustrates the alignment pin and the alignment recess of the package structure according to a second embodiment of the present invention.

### DETAILED DESCRIPTION OF THE INVENTION

### First Embodiment

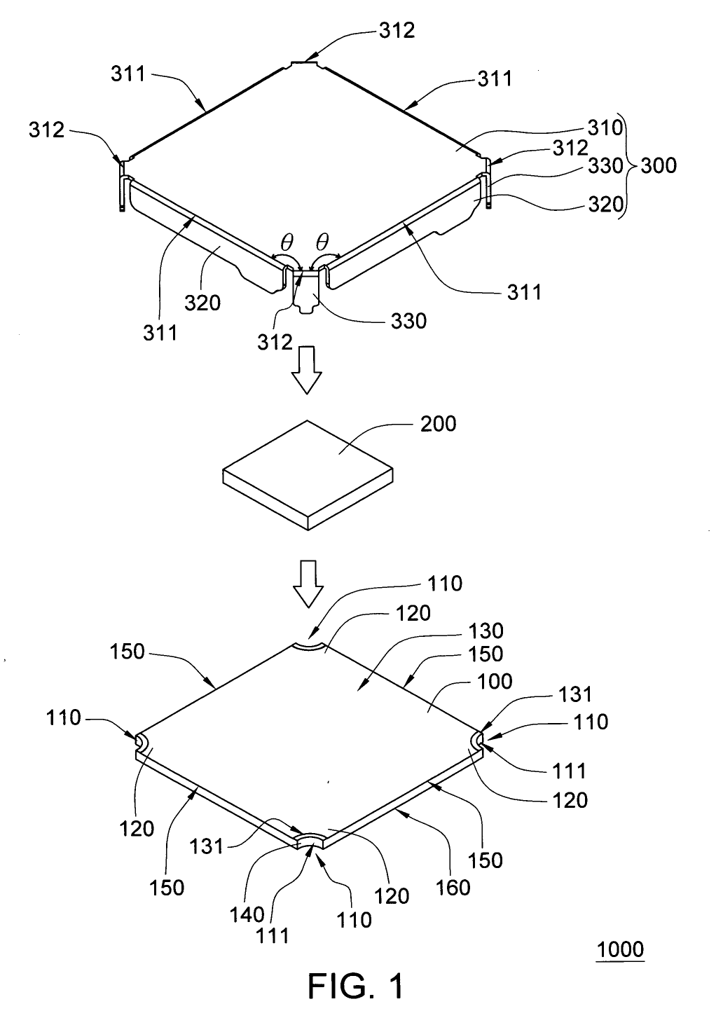

Please refer to FIG. 1. FIG. 1 is an exploded view of a package structure 1000 according to a first embodiment of the present invention. The package structure 1000 includes a substrate 100, a semiconductor device 200 and a shielding cap 300. The substrate 100 is for example a printed circuit board or a lead frame. The substrate 100 has at least an alignment recess 110. The alignment recess 110 is formed at a corner 120 of the substrate 100. In the present embodiment, the substrate 100 is substantially a quadrilateral structure. Therefore, the substrate 100 has four corners 120, and four alignment recesses 110 are respectively formed at four corners 120 of the substrate 100.

The semiconductor device 200 is for example a communication chip or a processing chip. The semiconductor device 200 is disposed on an upper surface 130 of the substrate 100. The semiconductor device 200 is for example disposed on the substrate 100 through wire-bonding or flip chip bonding.

The shielding cap 300 is disposed on the substrate 100 and covers the semiconductor device 200. The semiconductor device 200 is easily interfered with outer radiation, and the radiation generated by the semiconductor device 200 may affect electronic units nearby. Therefore, the shielding cap 300 is used for covering the semiconductor device 200 to provide good shielding. The shielding cap 300 includes a main board 310, at least a side board 320 and at least an alignment pin 330. The alignment pin 330 is inserted into the alignment recess 110. In the present embodiment, the shielding cap 300 includes four alignment pins 330 corresponding to four alignment recesses 110. The four alignment pins 330 are respectively inserted into the four alignment recesses 110.

The alignment pins 330 are disposed in the alignment recess 110 through welding. More specifically, as shown in FIG. 1, the substrate 100 includes welding copper foil 140. The copper foil 140 is formed on an inner wall 111 of the alignment recess 110 and on part of the upper surface 131 adjacent to the alignment recess 110. In the manufacturing process of the package structure 1000, solder paste is applied to part of the upper surface 131 adjacent to the alignment recess 110 through stencil printing. Then, the alignment pin 330 is welded to the alignment recess 110 through reflow. Generally speaking, part of the solder paste flows downward along the inner wall 111 of the alignment recess 110 during the reflow process. As a result, the alignment pin 330 is welded not only to part of the upper surface 131 adjacent the alignment recess 110 but also to the inner wall 111 of the alignment recess 110.

Furthermore, during the reflow process, the alignment pin 330 of the shielding cap 300 is inserted into the alignment recess 110. Therefore, the shielding cap 300 does not move easily, which greatly increases the stability of the manufacturing process.

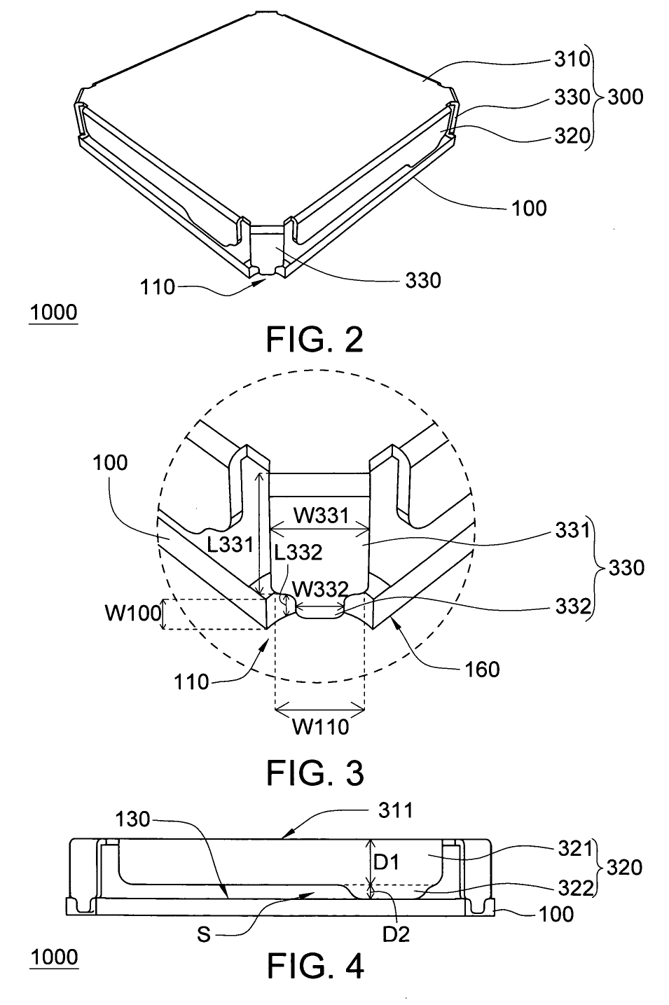

The substrate 110 is substantially a quadrilateral structure. The substrate 110 has four sides 150. The main board 310 is substantially an octagonal structure. The main board 310 has four long sides 311 and four short sides 312. Each long side 311 of the main board 310 corresponds to one side 150 of the substrate 100. Each short side 312 of the main board 310 corresponds to one corner 120 of the substrate 100. The angle between the long side 311 and the adjacent short side 312 of the main board 310 is substantially equal to 135°. The side board 320 of the shielding cap 300 extends from one of the long side 311 of the main board 310. The alignment pin 330 extends from one of the short side 312 of the main board 310. The side board 320 and the alignment pin 330 are substantially perpendicular to the main board 310. In the present embodiment, the main board 310, the side boards 320 and the alignment pins 330 are formed integrally. Please refer to FIG. 2. FIG. 2 is an assembled view of the package structure 1000 in FIG. 1. The space formed by the main board 310, the side board 320, the alignment pin 330 and the substrate 100 almost encapsulates the entire semiconductor device 200, for providing good shielding for the semiconductor device 200.

The structures of the alignment pin 330 and the side board 320 of the shielding cap 300 are described in details as follow.

Please refer to FIG. 3. FIG. 3 illustrates the alignment pin 330 and the alignment recess 110. The alignment pin 330 includes a first pin part 331 and a second pin part 332. The width W331 of the first pin part 331 is greater than the width W110 of the alignment recess 110 corresponding to the alignment pin 330. The width W332 of the second pin part 332 is smaller than the width 110 of the alignment recess 110 corresponding to the alignment pin 330. In other words, only the second pin part 332 with the smaller width is inserted into the alignment recess 110. Preferably, the length L332 of the second pin part 332 is one-half to two-third times the width W100 of the substrate 100. As a result, the end of the alignment pin 330 does not protrude from a lower surface 160 of the substrate 100. Therefore, the package structure 100 is able to be flatly disposed on another circuit board (not shown in drawings) and is not affected by the alignment pin 330.

Moreover, the length L331 of the first pin part 331 affects the height of the shielding cap 300. The user can decide the length L331 of the first pin part 331 according to the height and electrical properties of the semiconductor device 200. The shielding cap 300 of the present embodiment includes four alignment pins 330. The length L331 of the first pin part 331 of each alignment pin 330 is substantially the same. Therefore, the shielding cap 300 is not inclined.

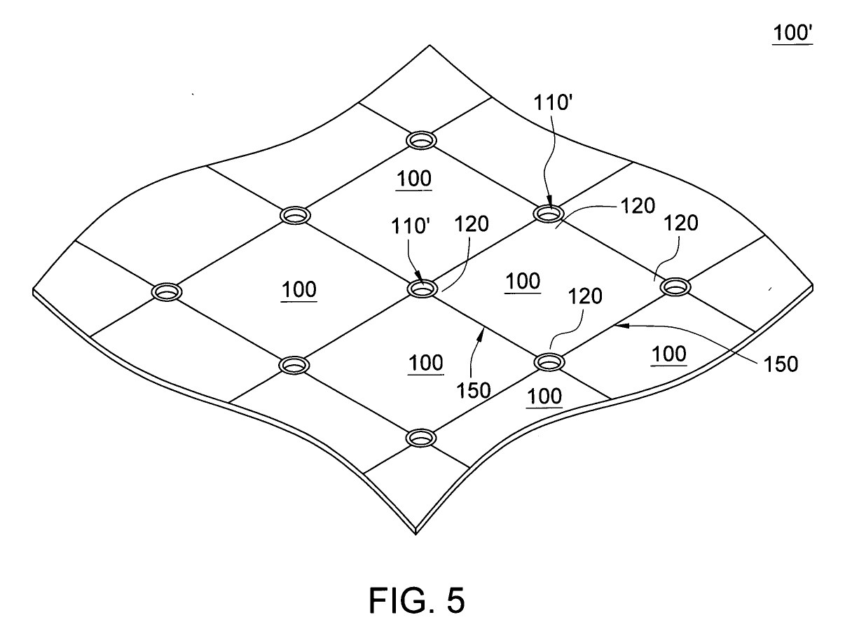

Please refer to FIG. 4. FIG. 4 is a lateral view of the package structure 1000 in FIG. 2. The side board 320 includes a first part 321 and a second part 322. The first part 321 of the side board 320 extends from one long side 311 of the main board 310. The second part 322 of the side board 320 extends from part of the edge of the first part 321 of the side board 320 and is against the upper surface 130 of the substrate 100. In other words, not the entire edges of the side board 320 are against the upper surface 130 of the substrate 100. There is still some air space S between the first part 321 of the side board 320 and the upper surface 130 of the substrate 100. During the reflow process, hot air flows into the shielding cap 300 through the air space S, so that the welding process can be performed successfully on the semiconductor device 200 and the shielding cap 300.

As shown in FIG. 4, the first part 321 of the side board 320 extends a first distance D1 from the edge of the main board 310, and the second part 322 of the side board 320 extends a second distance D2 from the edge of the first part 321 of the side board 320. Generally speaking, more air space S results in easier welding process but poor shielding capacity. On the contrary, less air space S results in harder welding process but better shielding capacity. Proved through repeated experiments, when the second distance D2 is preferably one-half to one times the first distance D1, welding process is performed successfully, and good shielding capacity can be achieved. In other words, preferably the height (the second distance D2) of the air space S is substantially one-third to one-half times the height (the sum of the first distance D1 and the second distance D2) of the shielding cap 300.

The shielding cap 300 of the present embodiment includes four side boards 320. The sum of the first distance D1 and the second distance D2 corresponding to each side board 320 is substantially the same. Also, the edge of the second part 322 of the side board 320 is straight. Therefore, the second part 322 of the side board 320 can be stably and flatly against the substrate 100, so the shielding cap 300 is not inclined.

Furthermore, the main board 310, the side board 320 and the alignment pin 330 of the shielding cap 300 are substantially flat structures. The side board 320 and the alignment pin 330 are separated apart from each other. Therefore, during the manufacturing process of the shielding cap 300, the outlines of the main board 310, the side board 320 and the alignment pin 330 are formed on a metal board, and then the metal board is bent and folded to form the structure of the shielding cap 300, which is easy to perform. Moreover, the manufacturing cost is lowered greatly.

Please refer to FIG. 5. FIG. 5 illustrates a mother substrate 100′. The above-described substrate 100 is formed by cutting a mother substrate 100′ having several circular holes 110′. After the semiconductor devices 200 and the shielding caps 300 are disposed at and welded to the mother substrate 100′, the mother board 100′ is cut along the line formed by the circular holes 110′ to form several package structures 1000. In other words, one circular hole 110′ of the mother substrate 100′ can be used as alignment recesses 110 (shown in FIG. 1) of four substrates 100. Also, the cross-section of each alignment recess 110 is a quarter of a circle. The alignment recesses 110 are at four corners 120 of the quadrilateral substrate 100. The edge between two adjacent corners 120 of the substrate 100 is a straight line. The alignment recess 110 only occupies the space of one quarter circle. Therefore, the shielding cap 300 does not occupy too much space of the substrate 100. The quadrilateral substrate 100 has four sides 150. Generally speaking, the possibility that pads or devices are disposed at the corners 120 of the substrate 100 is little. But the chance that pads are disposed on the sides 150 of the substrate 100 is larger. Therefore, the alignment recesses 110 formed at the corners 120 of the substrate 100 do not affect the arrangement of the pads or devices on the substrate 100. As a result, the package structure 1000 of the present embodiments further meets the trend of miniaturization.

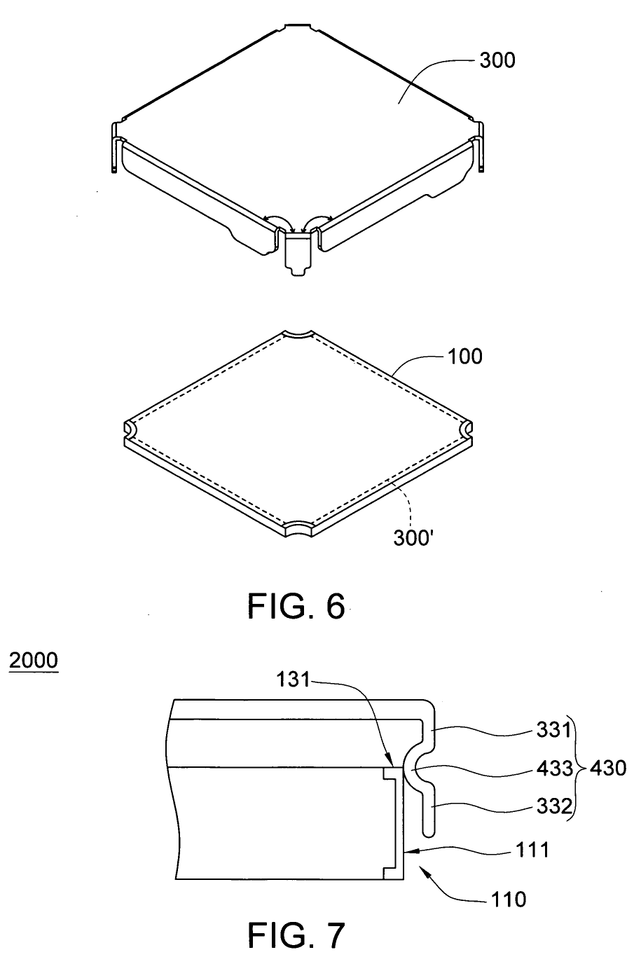

Please refer to FIG. 6, which illustrates a projection 300′ of the shielding cap 300 and the substrate 100. The projection 300′ of the shielding cap 300 on the substrate 100 is smaller than the substrate 100. Preferably, the distance between the edge of the projection 300′ that the shielding cap 300 projecting to the substrate 100 and the edge of the substrate 100 is larger than 0.1 mm. As a result, in the mother substrate 100′, the distance between two adjacent shielding caps 300 is greater than 0.2 mm. After the package structures 1000 are accomplished, the shielding caps 300 do not affect the cutter or laser beams during the cutting process.

### Second Embodiment

Please refer to FIG. 7. FIG. 7 illustrates the alignment pin 430 and the alignment recess 110 of the package structure 2000 according to a second embodiment of the present invention. The difference between the package structure 2000 of the present embodiment and the package structure 1000 of the first embodiment is that the alignment pin 430 of the present embodiment further includes a protruding part 433. Other parts are the same and not described repeatedly. The protruding part 433 is formed between the first pin part 331 and the second pin part 332 and leans against the inner wall 111 of the alignment recess 110. Because the protruding part 433 is formed between the first pin part 331 and the second pin part 332, the protruding part 433 leans right against the inner wall 111 on the top end of the alignment recess 110. When the solder paste is applied to part of the upper surface 131 adjacent to the alignment recess 110 and the alignment pin 430 is inserted into the alignment recess 110, the protruding part 433 contacts part of the solder paste. As a result, during the reflow process, part of the solder paste flows downward along the alignment pin 430 and the inner wall 111 of the alignment recess 110. Accordingly, the solder paste fills the entire space between the alignment pin 430 and the inner wall 111 of the alignment recess 110.

The package structure of the above embodiments of the present invention has many advantages because of the design of the substrate and the shielding cap. Some of the advantages are described as follow.

First, during the reflow process, the alignment pin of the shielding cap is inserted into the alignment recess. Therefore, the shielding cap does not move easily, which greatly increases the stability of the manufacturing process.

Second, the space formed by the main board, the side boards, the alignment pins and the substrate completed encapsulates the semiconductor device, so that the semiconductor device is provided with good radiation shielding.

Third, only the second pin part with smaller width is inserted into the alignment recess. And the length of the second pin part is one-half to two-third times the thickness of the substrate. Therefore, the end of the alignment pin does not protrude from the lower surface of the substrate. As a result, the package structure can be flatly disposed on another circuit board and is not affected by the alignment pin.

Fourth, the above-described shielding cap has four alignment pins. The length of the first pin part of each alignment pin is substantially the same. Therefore, the shielding cap is not inclined.

Fifth, some air space is between the first part of the side board and the upper surface of the substrate. During the reflow process, hot air flows into the shielding cap through the air space, so that welding can be successfully performed on the semiconductor device and the shielding cap during reflow process.

Sixth, proved through repeated experiments, when the above-described second distance is one-half to one times the first distance (that is, the height of the air space is one-third to one-half times the height of the shielding cap), success welding process and good shielding capacity can be achieved.

Seventh, the above-described shielding cap includes four side boards. The sum of the first distance and the second distance corresponding to each side board is substantially the same. And the edge of the second part of the side board is a straight line. Therefore, the second part of the side board can lean flatly and stably against the substrate, and the shielding cap is not inclined.

Eighth, the main board, the side boards and the alignment pins are substantially flat structure, and the side boards and the alignment pins are separated from each other. Therefore, during the manufacturing process of the shielding cap, the outlines of the main board, the side boards and the alignment pins are formed on a metal plate. After the metal plate is bent and folded, the three-dimensional structure of the shielding cap is formed. This manufacturing method of the shielding cap is very convenient, which lowers the manufacturing cost greatly.

Ninth, the alignment recess only occupies a quarter of a circle. Thus, the shielding cap does not occupy too much space of the substrate.

Tenth, the alignment recess formed at the corner of the substrate does not affect the arrangement of the contact pads or devices disposed on the substrate.

Eleventh, the distance between the edge of the projection of the shielding cap on the substrate and the edge of the substrate is greater than 0.1 mm. After several package structures are accomplished, the shielding caps do not affect the cutter or laser beam during the cutting process.

Twelfth, when the solder paste is applied to part of the upper surface adjacent to the alignment recess and when the alignment pin is inserted into the alignment recess, the protruding part of the second embodiment contacts part of the solder paste. As a result, during the reflow process, part of the solder paste flows downward along the alignment pin and the inner wall of the alignment recess, so that the solder paste fills the entire space between the alignment pin and the alignment recess.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A package structure comprising:
a substrate, having at least an alignment recess at a corner of the substrate;
a semiconductor device, disposed on an upper surface of the substrate; and
a shielding cap, covering the semiconductor device and comprising:
an alignment pin inserted into the alignment recess.

2. The package structure according to claim 1, wherein the substrate is substantially a quadrilateral structure, the substrate has four sides, and the shielding cap further comprises:
a main board, substantially being an octagonal structure and having four long sides and four short sides, the long sides of the main board corresponding to the sides of the substrate, the short sides of the main board corresponding to the four corners of the substrate; and
at least a side board, extending from one of the long sides of the main board, the side board substantially perpendicular to the main board;
wherein the alignment pin extends from one of the short side of the main board.

3. The package structure according to claim 2, wherein the side board comprises:
a first part, extending from one of the long sides of the main board; and
a second part, extending from part of the edge of the first part of the side board and leaning against the upper surface of the substrate.

4. The package structure according to claim 3, wherein the edge of the second part of the side board is a straight line.

5. The package structure according to claim 3, wherein the first part of the side board extends a first distance from the edge of the main board, the second part of the side board extends a second distance from the edge of the first part of the side board, and the second distance is one-half to one times the first distance.

6. The package structure according to claim 5, wherein the shielding cap comprises a plurality of side boards, the sum of the first distance and the second distance corresponding to each side board is substantially the same.

7. The package structure according to claim 2, wherein the side board and the alignment pin are separated from each other.

8. The package structure according to claim 2, wherein the angle between the long side and the short side of the main board is substantially 135°.

9. The package structure according to claim 1, wherein the alignment pin comprises:
a first pin part, the width of the first pin part greater than the width of the alignment recess corresponding to the alignment pin; and
a second pin part, the width of the second pin part smaller than the width of the alignment recess corresponding to the alignment pin, the length of the second pin part being one-half to two-third times the thickness of the substrate.

10. The package structure according to claim 9, wherein the alignment pin further comprises:
a protruding part, formed between the first pin part and the second pin part and leaning against the inner wall of the alignment recess.

11. The package structure according to claim 9, wherein the shielding cap comprises a plurality of alignment pins, the length of the first pin part of each alignment pin is substantially the same.

12. The package structure according to claim 1, wherein the cross-section of the alignment recess is a quarter of a circle.

13. The package structure according to claim 1, wherein the substrate comprises a welding copper foil on the inner wall of the alignment recess and part of the upper surface adjacent to the alignment recess.

14. The package structure according to claim 1, wherein the alignment pin is welded to the alignment recess.

15. The package structure according to claim 1, wherein a projection of the shielding cap on the substrate is smaller than the substrate.

16. The package structure according to claim 1, wherein the distance between the edge of a projection of the shielding cap on the substrate and the edge of the substrate is greater than 0.1 mm.

17. The package structure according to claim 1, wherein the edge between two corners of the substrate is a straight line.
